(19) United States
(12) Patent Application Publication
(10) Pub. No.: US 2021/0202804 A1
(43) Pub. Date: Jul. 1, 2021

(54) DISPLAY DEVICE

(71) Applicant: PlayNitride Display Co., Ltd., MiaoLi County (TW)

(72) Inventors: Sheng-Yuan Sun, MiaoLi County (TW); Ching-Hsiang Lin, MiaoLi County (TW)

(73) Assignee: PlayNitride Display Co., Ltd., MiaoLi County (TW)

(21) Appl. No.: 16/926,787

(22) Filed: Jul. 13, 2020

(30) Foreign Application Priority Data
Dec. 25, 2019 (TW) 108147577

(51) Int. Cl. H01L 33/58; H01L 25/075; H01L 33/50; H01L 33/62

(52) U.S. Cl. CPC H01L 33/58; H01L 25/0753; H01L 33/50; H01L 2933/0066; H01L 2933/0041; H01L 2933/0058; H01L 33/62

(57) ABSTRACT

A display device including a substrate, a circuit layer, a plurality of light-emitting devices, a first patterned light-absorbing layer, and a second patterned light-absorbing layer is provided. The circuit layer is disposed on the substrate. The light-emitting devices are distributed over the circuit layer. The first patterned light-absorbing layer is disposed on the circuit layer and located beside the light-emitting devices. The second patterned light-absorbing layer is disposed on the first patterned light-absorbing layer. A thickness of the second patterned light-absorbing layer is greater than a thickness of the first patterned light-absorbing layer. An optical density of the first patterned light-absorbing layer is greater than an optical density of the second patterned light-absorbing layer under a same thickness condition.

### CROSS-REFERENCE TO RELATED APPLICATION

This application claims the priority benefit of Taiwan patent application serial no. 108147577, filed on Dec. 25, 2019. The entirety of the above-mentioned patent application is hereby incorporated by reference herein and made a part of this specification.

### BACKGROUND

### Technical Field

The disclosure relates to a display device.

### Description of Related Art

Along with development of display technology, self-luminous displays with better color saturation and contrast have gradually drawn attentions. The self-luminous display is, for example, an Organic Light-Emitting Diode display (OLED display) or a micro-Light-Emitting-Diode display (micro-LED display).

A sub-pixel of a self-luminous display is a light-emitting device such as a micro-LED, and the lateral light emitted by the light-emitting device is easily to interfere with the surrounding pixels, and such a phenomenon may be called crosstalk. In order to effectively suppress the phenomenon of crosstalk, a method of forming a black matrix around each light-emitting device to absorb the lateral light emitted by the light-emitting device has been developed.

Fabrication of black matrix is generally achieved by using a photolithography process to process light-absorbing photoresist. However, after the light-absorbing photoresist is formed on a circuit layer around the light-emitting device, when a light source is emitting light to irradiate the light-absorbing photoresist for exposure, the circuit layer below the light-absorbing photoresist is liable to reflect light, which makes an exposure range of the light-absorbing photoresist to become inaccurate, and also causes poor development issue in later process.

On the other hand, if a light intensity of the light emitted by the light source is lowered in order to prevent the circuit layer from reflecting too much light, the light is liable to be absorbed by the light-absorbing photoresist and rarely reaches the bottom of the light-absorbing photoresist. In this way, the part of the light-absorbing photoresist to be left during development (i.e., the exposed part) is easily peeled from the bottom, which leads to process failed or unstable structure.

### SUMMARY

The disclosure is directed to a display device, which has a stable structure and a precise light-emitting region, and since its structure may effectively improve a process yield, the display device may have a lower cost.

An embodiment of the disclosure provides a display device including a substrate, a circuit layer, a plurality of light-emitting devices, a first patterned light-absorbing layer and a second patterned light-absorbing layer. The circuit layer is disposed on the substrate. The light-emitting devices are distributed over the circuit layer. The first patterned light-absorbing layer is disposed on the circuit layer and located beside the light-emitting devices. The second patterned light-absorbing layer is disposed on the first patterned light-absorbing layer. A thickness of the second patterned light-absorbing layer is greater than a thickness of the first patterned light-absorbing layer. An optical density of the first patterned light-absorbing layer is greater than an optical density of the second patterned light-absorbing layer under a same thickness condition.

According to the above description, in the display device of the embodiment of the disclosure, since the first patterned light-absorbing layer and the second patterned light-absorbing layer are adopted, wherein the thickness of the first patterned light-absorbing layer is smaller than the thickness of the second patterned light-absorbing layer, and under the same thickness condition, the optical density of the first patterned light-absorbing layer is greater than the optical density of the second patterned light-absorbing layer, when the second patterned light-absorbing layer is made for exposure, the first patterned light-absorbing layer may effectively block light of an exposure source from reaching the circuit layer and being reflected by the circuit layer. In this way, the problem of imprecise exposure region caused by reflected light from the circuit layer or the phenomenon that the second patterned light-absorbing layer peels off due to insufficient bottom exposure may be effectively avoided. In this way, the display device of the embodiment of the disclosure may have a stable structure and a precise light-emitting region. Moreover, the structure of the display device of the embodiment of the disclosure may help effectively improving the process yield, thereby reducing the manufacturing cost of the display device.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a partial cross-sectional view of a display device according to an embodiment of the disclosure.

FIG. 2 is a partial cross-sectional view of a display device according to another embodiment of the disclosure.

FIG. 3A to FIG. 3D are partial cross-sectional views of a fabrication process of a black matrix of the display device of FIG. 1.

FIG. 4 is a partial cross-sectional view of a display device according to another embodiment of the disclosure.

FIG. 5 is a partial cross-sectional view of a display device according to another embodiment of the disclosure.

### DESCRIPTION OF THE EMBODIMENTS

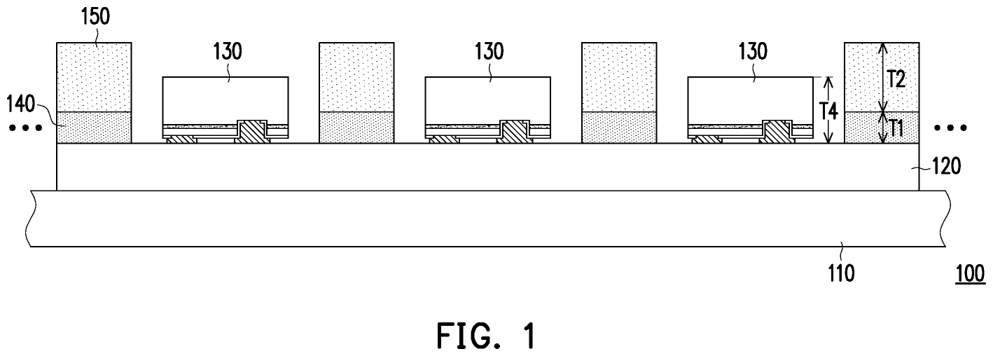

FIG. 1 is a partial cross-sectional view of a display device according to an embodiment of the disclosure. Referring to FIG. 1, the display device 100 of the embodiment includes a substrate 110, a circuit layer 120, a plurality of light-emitting devices 130, a first patterned light-absorbing layer 140 and a second patterned light-absorbing layer 150. The substrate 110 is, for example, a bottom plate of the display device 100, which is, for example, a glass substrate. However, in other embodiments, the substrate 110 may also be a silicon substrate or a substrate made of other material. The circuit layer 120 is disposed on the substrate 110. For example, the circuit layer 120 is, for example, a Thin Film Transistor (TFT) circuit layer of a display panel, which may include a plurality of TFTs and a plurality of scan lines and data lines respectively and electrically connected thereto or include other driving lines (for example, a power line, etc. In the embodiment, the circuit layer 120 is, for example, a metal circuit layer. The light-emitting devices 130 are distributed over the circuit layer 120, and are electrically connected to the circuit layer 120. In the embodiment, the light-emitting devices 130 are, for example, micro-LEDs, for example, micro-LEDs including an N-type semiconductor layer, a light-emitting layer, a P-type semiconductor layer, a N-electrode contacted the N-type semiconductor layer and a P-electrode contacted the P-type semiconductor layer stacked with each other, furthermore, the micro-LEDs means that the chip size is small than 100 μm and without a growth substrate to make the chip less thick. However, in other embodiments, the light-emitting devices 130 may also be Organic Light-Emitting Diodes (OLED) or other suitable light-emitting devices. Each of the light-emitting devices 130 may form a sub-pixel, and the light-emitting devices 130 may be arranged in various forms of two-dimensional matrix on the substrate 110 to form a plurality of display pixels arranged in an array, so that the light-emitting device 130 may form a display image when emitting light.

The first patterned light-absorbing layer 140 is disposed on the circuit layer 120 and located beside the light-emitting devices 130. In the embodiment, at least a part of the first patterned light-absorbing layer 140 is located between the light-emitting devices 130. For example, the first patterned light-absorbing layer 140 may surround each of the light-emitting devices 130. The second patterned light-absorbing layer 150 is disposed on the first patterned light-absorbing layer 140. In the embodiment, at least a part of the second patterned light-absorbing layer 150 is located between the light-emitting devices 130. For example, the second patterned light-absorbing layer 150 may surround each of the light-emitting devices 130. The first patterned light-absorbing layer 140 and the second patterned light-absorbing layer 150 may serve as a black matrix of the display device 100 to suppress the problem of crosstalk between two adjacent light-emitting devices 130.

In the embodiment, the thickness T2 of the second patterned light-absorbing layer 150 is greater than the thickness T1 of the first patterned light-absorbing layer 140, and an optical density of the first patterned light-absorbing layer 140 is greater than an optical density of the second patterned light-absorbing layer 150 under a same thickness condition. The higher the optical density is, the higher an absorptance for the light irradiated thereon is. When the optical density is equal to 1, the absorptance for the light irradiated thereon is 90%, i.e. 10% of the light may penetrate through, i.e., a penetration rate is 10%. When the optical density is equal to 2, the absorbance for the light irradiated thereon is 99%, and the penetration rate is 1%. When the optical density is equal to 3, the absorbance for the light irradiated thereon is 99.9%, and the penetration rate is 0.1%. When the optical density is equal to 4, the absorbance for the light irradiated thereon is 99.99%, and the penetration rate is 0.01%, and the others may be deduced by such analogy. In the embodiment, the optical density of the first patterned light-absorbing layer 140 is greater than 3, and the optical density of the second patterned light-absorbing layer 150 is greater than 2. A material of the first patterned light-absorbing layer 140 is, for example, light-absorbing photoresist or oxidized metal, and a material of the second patterned light-absorbing layer 150 is, for example, light-absorbing photoresist.

Moreover, in the embodiment, the thickness T1 of the first patterned light-absorbing layer 140 is smaller than 2 μm, and the thickness T2 of the second patterned light-absorbing layer 150 is greater than 5 μm. The light-emitting devices 130 are micro-LEDs, and a thickness T4 thereof is about 5 μm to 10 μm, i.e. the thickness T1 of the first patterned light-absorbing layer 140 is smaller than the thickness T4 of the light-emitting devices 130, but a sum of the thickness T1 of the first patterned light-absorbing layer 140 and the thickness T2 of the second patterned light-absorbing layer 150 is greater than the thickness T4 of the light-emitting devices 130.

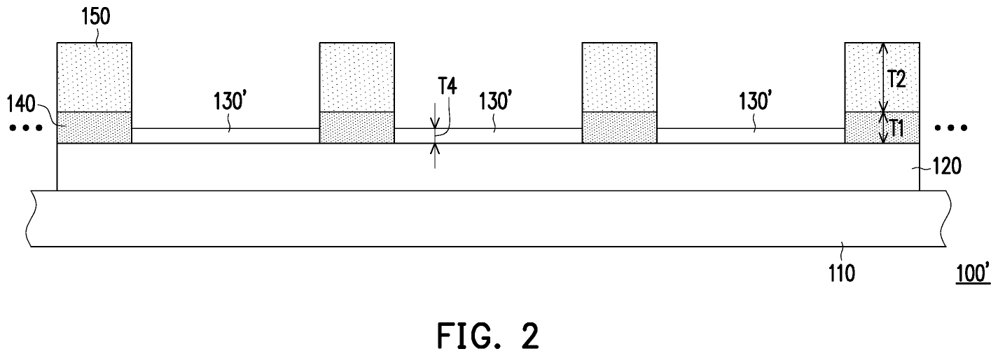

FIG. 2 is a partial cross-sectional view of a display device according to another embodiment of the disclosure. Referring to FIG. 2, the display device 100′ of the embodiment is similar to the display device 100 of FIG. 1, and differences there between are as follows. The light-emitting devices 130′ of the display device 100′ of the embodiment are OLEDs, the thickness T1 of the first patterned light-absorbing layer 140 is greater than the thickness T4 of the light-emitting devices 130, and the thickness T4 of the light-emitting devices 130 is about 100 nm to 500 nm.

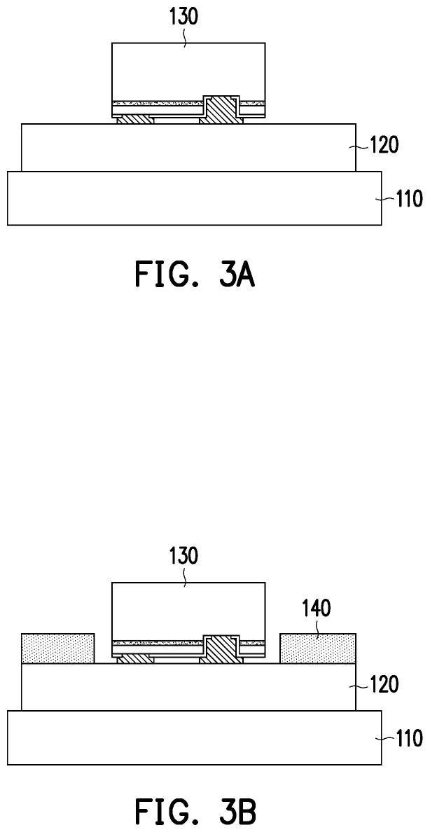

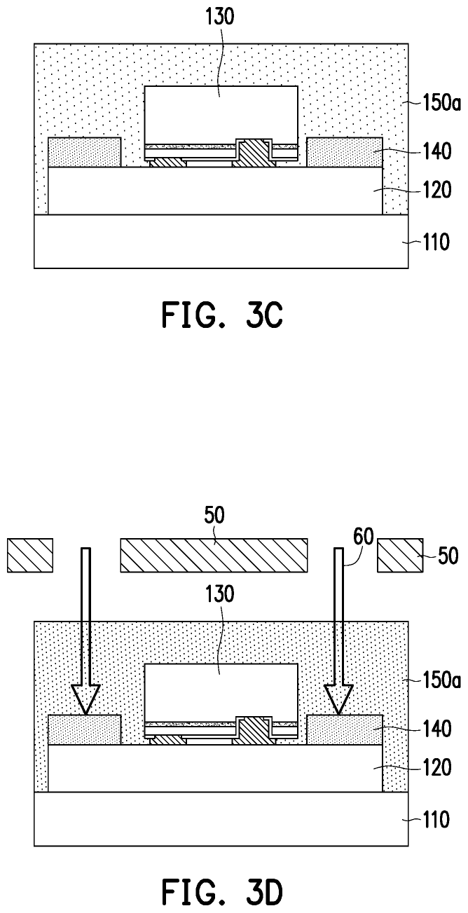

FIG. 3A to FIG. 3D are partial cross-sectional views of a fabrication process of a black matrix of the display device of FIG. 1. For simplicity's sake, the drawings only show a local area containing one light-emitting device 130, but the display device 100 actually includes a plurality of the light-emitting devices 130, as shown in FIG. 1. Referring to FIG. 3A, the circuit layer 120 is first fabricated on the substrate 110, and then the light-emitting devices 130 are attached on the circuit layer 120. Then, as shown in FIG. 3B, the first patterned light-absorbing layer 140 is formed around the light-emitting devices 130, and the formation method thereof may be a lithography process or a coating process.

Then, as shown in FIG. 3C, a light-absorbing photoresist material 150a is coated on all of the substrate 110, the circuit layer 120, the light-emitting devices 130 and the first patterned light-absorbing layer 140. Then, as shown in FIG. 3D, the light-absorbing photoresist material 150a is irradiated by exposure light 60 through the mask 50 to expose a specific region of the light-absorbing photoresist material 150a (for example, the region where the second patterned light-absorbing layer 150 of FIG. 1 is to be formed). In this case, because the first patterned light-absorbing layer 140 has better light absorption ability, the exposure light 60 may be prevented from being transmitted to the circuit layer 120 and reflected by the circuit layer 120, so as to improve the problem of imprecise exposure range on the light-absorbing photoresist material 150a caused by the reflected light. In the embodiment, the exposure light 60 is, for example, uv light. However, in other embodiments, the exposure light 60 may also be visible light, and the selected wavelength of the exposure light 60 is determined based on the light-absorbing photoresist material.

Finally, the light-absorbing photoresist material 150a is developed, and the portion of the light-absorbing photoresist material 150a irradiated by the exposure light 60 may be left to form the second patterned light-absorbing layer 150, such a light-absorbing photoresist may be called negative photoresist. In other words, the second patterned light-absorbing layer 150 is made by a photolithography process. However, the light-absorbing photoresist may also be a positive photoresist (i.e., the part of the light-absorbing photoresist to be removed during development of the exposed part) in other embodiments.

In the display device 100 of the embodiment, since the first patterned light-absorbing layer 140 and the second patterned light-absorbing layer 150 are adopted, wherein the thickness T1 of the first patterned light-absorbing layer 140 is smaller than the thickness T2 of the second patterned light-absorbing layer 150, and the optical density of the first patterned light-absorbing layer 140 is greater than the optical density of the second patterned light-absorbing layer 150 under the same thickness condition. When the second patterned light-absorbing layer 150 is made for exposure, the first patterned light-absorbing layer 140 may effectively block the light of an exposure source from reaching the circuit layer 120 and being reflected by the circuit layer 120. In this way, the problem of imprecise exposure region caused by the reflected light from the circuit layer 120 or the phenomenon that the second patterned light-absorbing layer 150 peels off due to insufficient bottom exposure may be effectively avoided. In this way, the display device 100 of the embodiment may have a stable structure and a precise light-emitting region. Moreover, the structure of the display device 100 of the embodiment may help effectively improve the process yield, thereby reducing the manufacturing cost of the display device 100.

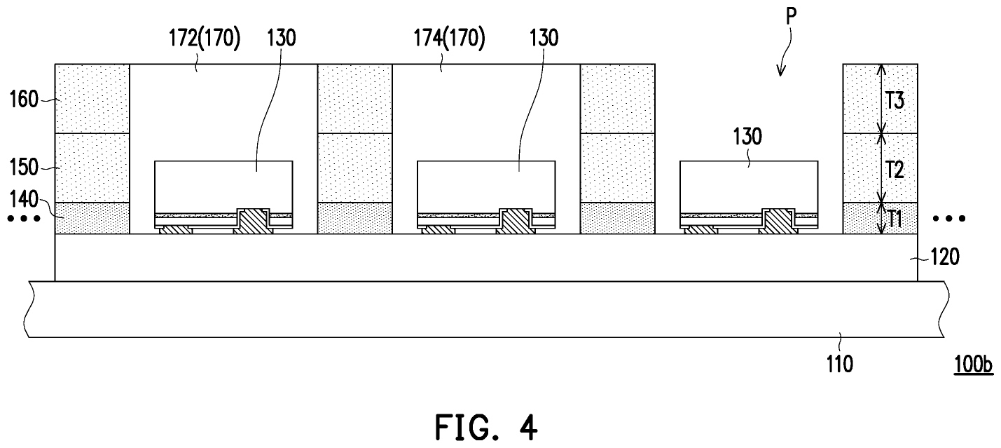

FIG. 4 is a partial cross-sectional view of a display device according to another embodiment of the disclosure. Referring to FIG. 4, the display device 100b of the embodiment is similar to the display device 100 of FIG. 1, and differences there between are as follows. The display device 100b of the embodiment further includes a third patterned light-absorbing layer 160 disposed on the second patterned light-absorbing layer 150. The second patterned light-absorbing layer 150 and the third patterned light-absorbing layer 160 have a plurality of openings P exposing the light-emitting devices 130. In the embodiment, the display device 100b further includes a plurality of quantum dot layers 170 respectively disposed on at least a part of the light-emitting devices 130, for example, the quantum dot layers 170 are disposed in at least a part of the openings P. For example, the light-emitting devices 130 may emit blue light, and the quantum dot layer 170 may be divided into quantum dot layer 172 that may convert blue light into red light, and quantum dot layer 174 that may convert blue light into green light. By configuring the quantum dot layer 172 on a part of the light-emitting devices 130 and the quantum dot layer 174 on another part of the light-emitting devices 130. However, the quantum dot layer is not configuring on the remained light emitting device 130 may be formed sub-pixels of three color of red, green and blue to form a color image. However, in another embodiment, the light-emitting devices 130 may also emit uv light, and the quantum dot layer is configured on each light-emitting device 130, and the quantum dot layers may respectively convert the uv light into red light, green light, and blue light, such that the color image may also be produced. Alternatively, the quantum dot layer also may generate other color light or also may emit other color light through other light-emitting devices in other embodiments, which are not limited by the disclosure.

In the embodiment, the thickness T3 of the third patterned light-absorbing layer 160 is greater than the thickness T1 of the first patterned light-absorbing layer 140. Moreover, in the embodiment, under the same thickness condition, the optical density of the first patterned light-absorbing layer 140 is greater than the optical density of the third patterned light-absorbing layer 160. The third patterned light-absorbing layer 160 may adopt either the same or similar material and thickness as the second patterned light-absorbing layer 150, but the disclosure is not limited thereto.

Moreover, at least a part of the light-emitting devices 130 of the display device 100 of FIG. 1 may also be configured with the quantum dot layers 170 of FIG. 4 to form other embodiments.

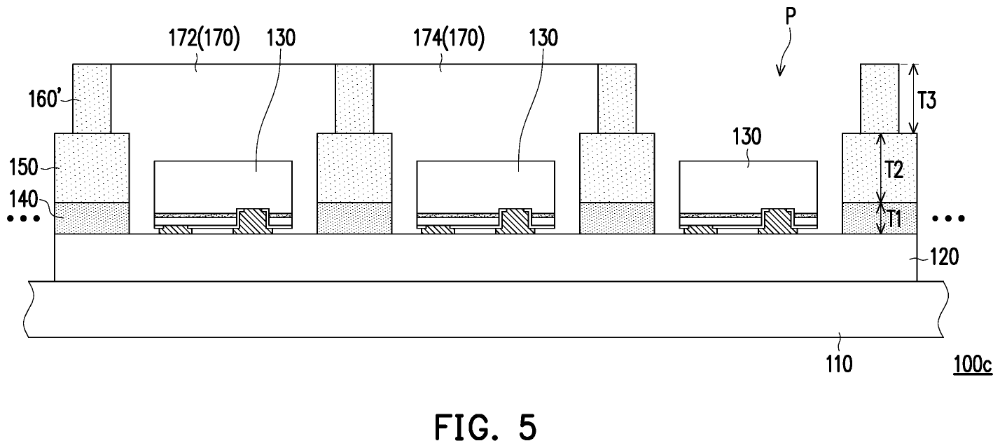

FIG. 5 is a partial cross-sectional view of a display device according to another embodiment of the disclosure. Referring to FIG. 5, the display device 100c of the embodiment is similar to the display device 100b of FIG. 4, the differences between both are as follows. The third patterned light-absorbing layer 160′ of the display device 100c of the embodiment is disposed on the second patterned light-absorbing layer 150 in retraction in order to prevent the stacked structure of the second patterned light-absorbing layer 150 and the third patterned light-absorbing layer 160′ from forming an undercut, so as to ensure a better filling of the quantum dot layer 170 in the openings P. When the third patterned light-absorbing layer 160 is designed to have the same width as the second patterned light-absorbing layer 150, if exposure alignment is slightly shifted, it is easy to cause one side of the third patterned light-absorbing layer 160 to protrude out from the second patterned light-absorbing layer 150, which may result in a lower yield. In the embodiment, the third patterned light-absorbing layer 160′ is disposed on the second patterned light-absorbing layer 150 in retraction, so that a width of the third patterned light-absorbing layer 160′ is slightly smaller than a width of the second patterned light-absorbing layer 150, which may effectively improve a tolerance for an exposure error.

In summary, in the display device of the embodiment of the disclosure, since the first patterned light-absorbing layer and the second patterned light-absorbing layer are adopted, wherein the thickness of the first patterned light-absorbing layer is smaller than the thickness of the second patterned light-absorbing layer, and under the same thickness condition, the optical density of the first patterned light-absorbing layer is greater than the optical density of the second patterned light-absorbing layer, when the second patterned light-absorbing layer is made for exposure, the first patterned light-absorbing layer may effectively block light of an exposure source from reaching the circuit layer and being reflected by the circuit layer. In this way, the problem of imprecise exposure region caused by reflected light from the circuit layer or the phenomenon that the second patterned light-absorbing layer peels off due to insufficient bottom exposure may be effectively avoided. In this way, the display device of the embodiment of the disclosure may have a stable structure and a precise light-emitting region. Moreover, the structure of the display device of the embodiment of the disclosure may help effectively improve the process yield, thereby reducing the manufacturing cost of the display device.

What is claimed is:

1. A display device, comprising:
a substrate;
a circuit layer, disposed on the substrate;
a plurality of light-emitting devices, distributed over the circuit layer;
a first patterned light-absorbing layer, disposed on the circuit layer, and located beside the light-emitting devices; and
a second patterned light-absorbing layer, disposed on the first patterned light-absorbing layer, wherein a thickness of the second patterned light-absorbing layer is greater than a thickness of the first patterned light-absorbing layer, an optical density of the first patterned light-absorbing layer is greater than an optical density of the second patterned light-absorbing layer under a same thickness condition.

2. The display device as claimed in claim 1, further comprising:
a plurality of quantum dot layers, respectively disposed on a part of the light-emitting devices.

3. The display device as claimed in claim 2, wherein the light-emitting devices are micro light-emitting diodes.

4. The display device as claimed in claim 1, wherein at least a part of the first patterned light-absorbing layer is located between the light-emitting devices.

5. The display device as claimed in claim 1, wherein the thickness of the first patterned light-absorbing layer is smaller than 2 μm.

6. The display device as claimed in claim 1, wherein the optical density of the first patterned light-absorbing layer is greater than 3.

7. The display device as claimed in claim 2, wherein the thickness of the second patterned light-absorbing layer is greater than 5 μm.

8. The display device as claimed in claim 7, wherein the optical density of the second patterned light-absorbing layer is greater than 2.

9. The display device as claimed in claim 1, wherein the thickness of the first patterned light-absorbing layer is smaller than a thickness of the light-emitting devices.

10. The display device as claimed in claim 1, wherein the light-emitting devices are organic light-emitting diodes.

11. The display device as claimed in claim 2, further comprising:
a third patterned light-absorbing layer, disposed on the second patterned light-absorbing layer, wherein the second patterned light-absorbing layer and the third patterned light-absorbing layer have a plurality of openings exposing the light-emitting devices, and the quantum dot layers are disposed in the openings.

12. The display device as claimed in claim 11, wherein a thickness of the third patterned light-absorbing layer is greater than the thickness of the first patterned light-absorbing layer.

13. The display device as claimed in claim 11, wherein under a condition of a same thickness, the optical density of the first patterned light-absorbing layer is greater than an optical density of the third patterned light-absorbing layer.
